(19) United States
(12) Patent Application Publication
(10) Pub. No.: US 2025/0040326 A1
(43) Pub. Date: Jan. 30, 2025

(54) OPTOELECTRONIC COMPONENT, OPTOELECTRONIC DEVICE AND METHOD FOR MANUFACTURING A COMPONENT

(71) Applicant: ams-OSRAM International GmbH, Regensburg (DE)

(72) Inventors: Norwin von Malm, Nittendorf (DE); Alvaro Gomez-Iglesias, Regensburg (DE); Harald König, Bernhardswald (DE)

(21) Appl. No.: 18/716,880

(22) PCT Filed: Dec. 9, 2022
(86) PCT No.: PCT/EP2022/085135

§ 371 Date: Jun. 5, 2024

(30) Foreign Application Priority Data
Dec. 9, 2021 (DE) 10 2021 132 559.5

(51) Int. Cl. H01L 33/62; H01L 33/06; H01L 33/20; H01L 33/46; H01L 33/50; H01L 33/56

(52) U.S. Cl. CPC H01L 33/62; H01L 33/06; H01L 33/20; H01L 33/46; H01L 33/502; H01L 33/56; H01L 2933/0025; H01L 2933/005; H01L 2933/0066

(57) ABSTRACT

In an embodiment an optoelectronic component with an epitaxial layer sequence comprises a functional inner region having a first electrical contact and a second electrical contact opposite the first electrical contact, as well as semiconductor layers arranged between the first electrical contact and the second electrical contact configured to generate light. The semiconductor layers comprise a base area that increases towards the second electrical contact. A dielectric passivation layer is arranged on the side walls of the semiconductor layers. A mirror layer surrounds the passivation layer at a distance thereby forming a gap. The second electrical contact and a plane of the gap surrounding the second electrical contact form a common light-emitting surface.

### CROSS-REFERENCE TO RELATED APPLICATIONS

This patent application is a national phase filing under section 371 of PCT/EP2022/085135, filed Dec. 9, 2022, which claims the priority of German patent application 10 2021 132 559.5, filed Dec. 9, 2021, each of which is incorporated herein by reference in its entirety.

### TECHNICAL FIELD

The present invention relates to an optoelectronic component and a method of manufacturing such a component. The invention also relates to an optoelectronic device.

### BACKGROUND

Requirements for optoelectronic components as well as applications with such components demand ever smaller dimensions of the light-emitting surface. The size of such optoelectronic components, also known as μ-LEDs, is now in the range of a few micrometers, in particular smaller than 70 μm and in particular smaller than 20 μm down to 1 μm to 2 μm. Such μ-LEDs exhibit considerable side emission, in particular with the small lateral diameters of less than 20 μm described above, and are often designed as volume emitters. Depending on the application, this side emission can be disadvantageous due to the limited acceptance angle of an optic arranged on it. In addition, with such side emission there is a higher probability of optical crosstalk between different pixels, so that additional measures are required to prevent such crosstalk.

It is known from the state of the art to cover the side walls of such μ-LEDs with a metallic mirror layer after electrical passivation, which serves as a reflector and directs the light emitted to the side towards a light-emitting surface. However, the reflectivity of such layers depends heavily on the properties of the side surfaces of the μ-LED. Measures that serve to improve the quantum efficiency, i.e. to improve the light generation within an active area of the μ-LED, also play a role here. Depending on the application and design, such measures make it more difficult to create a mirror layer with the highest possible reflectivity.

### SUMMARY

Embodiments provide optoelectronic components, particularly in the form of μ-LEDs, in which side emission can be used with the best possible efficiency.

The inventors have recognized that an improvement is influenced, among other things, by a spatial separation of the functionality of the electrical passivation from the functionality of the optical reflector. Those parts of an epitaxial layer sequence that are not needed for the functionality of light generation can at least partially take over the functions of a reflector. In other words, the electrical passivation and the deflection of the side emission are separated locally and spatially so that the two measures can be optimized individually and separately from each other.

For this purpose, a functional component is structured in an epitaxial layer sequence as an inner region of an optoelectronic component by means of mesa etching and side walls of the semiconductor layers of the inner region are surrounded by a transparent dielectric layer. A reflective coating to produce a mirror layer around the inner region with the semiconductor layers is formed in a subsequent step and in a neighboring region of the layer sequence.

The mirror layer and the passivation applied to the side walls of the semiconductor layers are spatially separated from each other, so that not only a desired radiation characteristic can be achieved by the shape and formation of the mirror layer, but the two layers can also be processed and optimized separately from each other.

In one aspect of the invention, an optoelectronic component with an epitaxially grown layer sequence is thus proposed. The epitaxially grown layer sequence comprises a functional inner region which has a first electrical contact and a second electrical contact opposite the first electrical contact. Semiconductor layers configured to generate light are arranged between the first electrical contact and the second electrical contact. The semiconductor layers configured to generate light have a base area that increases towards the second electrical contact. In other words, the semiconductor layers become larger or wider in the direction of the second electrical contact.

Furthermore, a dielectric passivation layer is provided on side walls or side surfaces of the semiconductor layers configured for light generation. In addition to pure passivation, the dielectric passivation layer can also include other functionalities, in particular, for example, to increase the band gap in the region of the side walls of the semiconductor layers and in particular in the region of an active layer. The passivation layer is thus also used to improve the quantum efficiency of the semiconductor layers configured for light generation. A mirror layer now surrounds the passivation layer, forming a gap. Accordingly, the mirror layer is spaced apart from the passivation layer according to the invention, so that a gap is formed between the two layers. The second electrical contact and the plane of the formed gap surrounding the second electrical contact then form the light-emitting surface of the optoelectronic component.

With the proposed optoelectronic component, a spatial separation between the mirror layer and the passivation layer is achieved so that they can be optimized independently of each other during manufacture. In particular, this makes it possible for defect etching by the dielectric passivation layer to be carried out independently of and optimized for the subsequent formation of the mirror layer. This allows the reflectivity of the mirror layer to be optimized without any disadvantages or compromises having to be made in the formation of the passivation layer and thus in the quantum efficiency of the semiconductor layers intended for light generation.

In some aspects, the mirror layer can be electrically conductive and make electrical contact with the second electrical contact via the light-emitting surface. In this way, a vertical component is formed in which the electrical contacts are located on opposite, different sides. In one aspect, an electrically conductive transparent material, for example ITO, is provided for this purpose, which extends at least partially over the gap and connects the second electrical contact in a conductive manner, in particular to the mirror layer. The electrically conductive transparent material can be formed flat over the gap for this purpose. Alternatively, it is also possible for the electrically conductive transparent material to extend as a bridge from the second electrical contact at least to the mirror layer. Such a design would have the advantage that the light-emitting surface is only partially covered by the transparent electrically conductive material, so that in this way absorption, albeit slight, by the electrically conductive transparent material or light scattering from it is avoided.

Another aspect deals with the material within the gap formed by the distance between the mirror layer and the electrical passivation layer. In one embodiment, this space is filled with a transparent, non-conductive material. This differs in some aspects from the dielectric passivation layer. In some embodiments, the gap formed can also remain at least partially free of a solid material and, for example, be filled only with a gas, in particular air. In such a case, a bridge extending across the gap would be formed as a bridge between the second electrical contact and the mirror layer.

In a further alternative embodiment, it is proposed to convert the light generated by the semiconductor layers provided for light generation. For this purpose, in some aspects the space between the mirror layer and the dielectric passivation layer is filled with a converter material. In particular, this may comprise quantum dots or a polymer provided with converter particles or organic luminescent molecules. Quantum dots are the more suitable material for components with very small dimensions in the range below 10 μm. A converter in the interstitial space can be used to generate mixed light, for example by selecting and concentrating the converter material accordingly, as well as full conversion of the light generated by the semiconductor layers.

For full conversion, some aspects also provide for the second electrical contact to be designed with a reflective layer so that no light is emitted from the light-emitting surface via the surface of the second electrical contact, but instead always reaches the gap filled with converter material and is converted there. Several of these components can be combined to form a pixel for generating a red, green and blue hue.

Another aspect deals with the embodiment of the mirror layer. In some aspects, this can comprise a metallic electrically conductive layer, which is formed in particular from silver, aluminum, gold, platinum or another material that is highly reflective for the generated light. In embodiments, the thickness of such a metallic electrically conductive mirror layer is in the range of a few 10 nm to a few 100 nm. In order to ensure the lowest possible surface resistance and thus a current transport to the second contact, the electrically conductive mirror layer can be formed with a particularly conductive material whose surface resistance is as low as possible.

It is also possible for the mirror layer to have several layers, in particular several metallic conductive layers. In an alternative embodiment, the mirror layer is designed as a DBR mirror, i.e. with a sequence of layers of different refractive indices. Such a DBR mirror can, among other things, be tuned to the wavelength of the light generated by the semiconductor layers so that it is reflected with particularly high efficiency and directed towards the light-emitting surface.

In some embodiments, the gap is designed as a circular structure, a square structure or a polygon in a plan view of the light-emitting surface. Furthermore, the gap can take on different shapes, for example as a funnel with straight walls or with curved, for example parabolic, walls. In some aspects, the mirror layer thus has a parabolic shape that opens in the direction of the light-emitting surface. In such an embodiment, a focal point of the parabolic shape can be located in the inner region and in particular in the region of an active zone of the semiconductor layers serving to generate light.

In another aspect, an opening angle between the mirror layer and a normal to the light-emitting surface is larger than an opening angle between the side walls of the semiconductor layers configured to generate light and the normal to the light-emitting surface. Consequently, an opening angle of the gap (ultimately the inclination of the mirror layer) is different from the opening angle of the semiconductor layers configured for light generation (the inclination angle of the side walls of the inner region), so that the side walls of the semiconductor layers and the mirror layer are not parallel to each other. Such a non-parallel course would be present, for example, in the above-mentioned parabolic shape as well as in a funnel-shaped form, provided that the opening angle of the funnel formed by the mirror layers is different from the opening angle defined by the side surfaces of the semiconductor layers configured for light generation.

Some further aspects deal with the distance of the mirror layer from the dielectric passivation layer. The distance is essentially determined by the manufacturing process of the optoelectronic component according to the proposed principle. In some aspects, a ratio of the distances from the mirror layer to the centers of the first and second contacts, respectively, is different from a ratio of the distances between the sidewalls of the semiconductor layers configured to generate light and the centers of the first and second contacts, respectively. Depending on the inclination of the mirror layers and/or the side walls, the ratios can be adapted to the desired radiation behavior.

In another aspect, a distance between the mirror layer and the sidewalls of the semiconductor layers configured to generate light in the region of the first contact depends on an angle resulting from a normal to the light emitting side and the sidewalls of the semiconductor layers configured to generate light. In other words, this means that if the side walls are more inclined, the inner region has a larger opening angle and thus the distance in the area of the first contact is correspondingly larger. Consequently, an imaginary line that runs parallel to the normal through the lower edge area of the mirror layer in the area of the first contact does not touch or intersect the side surfaces of the semiconductor layers in an extension towards the light exit side.

In some aspects, the distance is given by at least twice an are tangent of an angle between a normal to the light emitting side and the sidewalls of the semiconductor layers configured to generate light.

Other aspects deal with the design of the semiconductor layers configured for light generation. As mentioned at the beginning, these are part of an epitaxial layer sequence or are formed from it. Accordingly, the semiconductor layers configured for light generation comprise a first semiconductor layer provided with a first doping type, which is electrically connected to the first contact. Likewise, the semiconductor layers comprise a second semiconductor layer with a second doping type, which is electrically connected to the second contact. An active layer is arranged between the first and second semiconductor layers. In addition to the semiconductor layers, additional current expansion layers can also be provided. The doping may be constant, but in some aspects also has a doping profile.

In some aspects, the active layer has one or more quantum wells. In the case of multiple quantum wells, these are often composed of a ternary or quaternary material system, which includes aluminum in different concentrations. The different amount of aluminum leads to different band gaps, resulting in the above-mentioned quantum well structure consisting of several individual quantum wells and barrier layers in between. In a further aspect, quantum well intermixing can be provided, which is formed in the area of the side walls. A quantum well intermixing leads to a change in the band structure of the active zone in the area of the side walls and thus causes an electrical repulsion of charge carriers in this area. Alternatively, an increase in the band gap and the associated electrical repulsion in the area of the side walls can also be achieved by a regrowth process, i.e. by overgrowing the side walls with a semiconductor with a larger band gap.

In some aspects, the epitaxial layer sequence on which the mirror layer is deposited comprises at least one of the above-mentioned semiconductor layers. This follows from the manufacturing process, since both the inner region and the epitaxial layer sequence to which the mirror layer is applied are structured from the epitaxial layer sequence. It is also conceivable that parts of the active layer of the inner region can be found in the layer sequence to which the mirror layer is applied.

The optoelectronic component is formed from the epitaxial layer sequence by structuring one or more inner regions with semiconductor layers intended for light generation and surrounding them with a gap. Areas of the epitaxial layer sequence, which thus form the edge of the gap, are overgrown with the mirror layer, resulting in the proposed optoelectronic component. This has the advantage that the epitaxial layer sequence can be uniformly grown as a whole and the optoelectronic components can then be processed from the epitaxial layer sequence in further process steps.

In a further aspect, the optoelectronic component comprises an insulating layer on the side of the first contact. This has at least two openings provided with an electrically conductive material. A first opening is designed such that the material present therein contacts the first contact. A second opening, on the other hand, is arranged in an area in which the conductive material present therein contacts at least one area of the mirror layer or the area supporting the mirror layer.

Another aspect deals with an electronic device with a plurality of components according to the proposed principle. As already mentioned, the optoelectronic component is formed from an epitaxially grown layer sequence, so that this epitaxially grown layer sequence is suitable not only for manufacturing and producing a single component, but also for a plurality of components according to the proposed principle.

In such a case, the components in the epitaxial layer sequence are arranged in rows and columns and have a plurality of contact areas on one side. In some embodiments, the optoelectronic components of such a device are designed with a common contact, for example a common n-contact. In some embodiments, this is formed by the transparent material applied to the second contact, which is in contact with the mirror layer of at least some of the components.

According to the invention, in addition to the plurality of components, the optoelectronic device also comprises a drive layer on which the plurality of components is arranged and electrically contacted. The control layer can be made of a material that is different from the epitaxial layer sequence and has a plurality of contact areas on its surface that correspond to the contact areas of the epitaxial layer sequence and the optoelectronic components. Supply lines, control circuits and necessary supply elements for controlling and supplying the optoelectronic components are provided in the control layer. In this way, an array of components can be created that is suitable for displays or other light-emitting applications, for example. A distance between two components can correspond to at least one distance between two opposing points of the mirror layer in the area of the light-emitting surface. In some embodiments, the distance between the optoelectronic components can also be greater. In this embodiment in particular, it is possible to partially introduce converter materials into the gaps in order to form an array of components for generating red, green and blue color.

It is also possible to apply further light-forming or light-converting structures to the light-emitting side, for example to create pixels of different colors.

Another aspect deals with a method for manufacturing an optoelectronic component according to the proposed principle.

The basic principle here is to structure an epitaxial layer sequence from two sides and form it with mesa trenches. The positions of these trenches are designed in such a way that the desired gap with its respective side flanks is formed on the epitaxial layer sequence by a second mesa etching process from another side. In this way, the side flanks of the inner region can be produced separately from the side flanks of the subsequent mirror layer and thus optimized for the appropriate application. In particular, it is also possible in this process to subject the side flank of the inner region to further measures, for example to eliminate possible defects in the area of the active layer of the inner region. In addition, the passivation layer for the inner region can be formed independently of the subsequent mirror layer so that this can be optimized for the application.

In one aspect of the proposed method for manufacturing an optoelectronic component, a growth substrate is provided to which a planar epitaxial layer sequence is applied. The layer sequence comprises an n-doped semiconductor layer, a p-doped semiconductor layer and an active layer arranged in between. The two-dimensional epitaxial layer sequence can be optimized for the desired light generation (in particular the color of the generated light) and the resulting requirements. In this respect, it is therefore possible to form the active layer as a simple pn junction, as a quantum well or as a multiple quantum well made from one of the ternary or quaternary material systems. The epitaxial layer sequence is thus optimized for the respective material system and for light generation.

In addition to the n-doped and p-doped semiconductor layers, other structures can also be part of the epitaxial layer sequence in this context. These include current distribution layers, but also contact layers, which form the subsequent contacts of the inner region and thus the vertical μ-LED. The doping of the individual semiconductor layers can be adjusted to requirements; it can be constant, but can also follow a doping profile.

In a subsequent second step, a first surface of the epitaxial layer sequence is structured. This can be done, for example, by applying and exposing a photomask layer. In a top view of the first surface, the structuring is carried out in such a way that a surface area accessible to a first etching process is formed, which encloses an inner surface. This inner surface forms the surface of the subsequent inner region and thus one side of the μ-LED. In a particular aspect, the inner surface forms the surface of the μ-LED opposite the later light-emitting side.

After structuring, an initial etching process is carried out, creating a mesa trench in the accessible surface area. The formation of the mesa trench creates an inner region with an inclined side flank, which later forms the μ-LED of the electronic component. The mesa trench is etched at least to a depth that exposes and cuts through the active layer thickness of the epitaxial layer sequence.

A second surface of the epitaxial layer sequence, which is opposite the first surface, is then structured. The structuring can be carried out in a similar way by forming a photoresist layer and subsequent exposure. From a top view of this second surface, areas are now accessible for a second etching process that lie at least partially above the formed mesa trench. The exposed material of the epitaxial layer sequence is now removed by a subsequent second etching process until the mesa trench is opened from the other side. This opening thus creates a continuous gap that encloses the inner region, whereby the side flanks of the remaining epitaxial layer sequence opposite the inner region are also partially inclined relative to a normal.

In one aspect, the step of forming the epitaxial layer sequence also comprises forming a first electrical contact layer which forms the first surface. Alternatively, a first electrical contact layer and a structured insulation layer applied thereto can also be formed, in which case the structured insulation layer forms the first surface. During the formation of the epitaxial layer sequence, it is also possible to provide a second electrical contact layer, which subsequently forms the second surface.

In one aspect, during structuring of a first surface, it is provided to also generate quantum well intermixing in regions of the active layer which, in extension, include the interface between the surface region accessible to the first etching process and the inner surface. In other words, structuring is carried out for this purpose, which not only serves to form the mesa trench, but also supports the generation of quantum well intermixing in the regions of the active layer, which later form the edge region of the inner region and thus the edge region of the active layer of the μ-LED.

In this context, a structuring with the accessible surface areas can have different shapes in plan view. For example, it is possible to form the accessible surface areas in the shape of a circular ring, with the center of the circular ring forming the center of the inner region. Alternatively, it is possible to shape the accessible surface areas in the form of polygons or a square. In particular, it is possible for the shape of the surface areas to be based on the crystal planes of the semiconductor structure. In this context, it is also conceivable to shape the outer edge differently to the inner edge of the accessible surface area. In this way, inner regions can be defined whose shape is different from the shape of the later surrounding gap.

In some aspects, the step of creating a mesa trench also comprises an optional treatment of the side surfaces of the inner region to reduce defects in a surface region of the active layer. A possible example of this is a regrowth process in which a band structure change is carried out in the active layer by epitaxially applying a suitable semiconductor material to the surface area of the inner region. If this semiconductor material is also applied to the remaining side edges of the epitaxial layer sequence, these can be removed again by the second etching process carried out later. It is also possible to passivate one surface of the side faces of the inner region. This can be done instead of the optional treatment, but also after such a treatment.

Further aspects deal with the structuring of the second surface opposite the first surface. For this purpose, a carrier can be arranged on the first surface, whereby the epitaxial layer sequence can be rebonded. In this way, the originally intended growth substrate can be at least partially removed and the second surface exposed. This can be additionally processed in further steps, for example by applying current-splitting layers or a second electrical contact layer. In some aspects, the second electrical contact layer can also form part of the structuring required for the subsequent second etching process. In some aspects, the areas of the second surface accessible to the second etching process are outside the inner region formed by the first etching process.

The second etching process creates a side flank of the epitaxial layer sequence, which can be inclined differently depending on the design of the etching process. For example, it is possible that the side flank of the epitaxial layer sequence opposite the inner region is inclined more towards a normal to the second surface than the side walls of the inner region. In other words, the side flank opposite the inner region opens up more than the side walls of the inner region itself. Alternatively, it is also possible to divide the second etching process into several individual steps, so that the side flank of the epitaxial layer sequence opposite the inner region has a parabolic course with a decreasing diameter of the resulting gap in the direction of the first surface.

Another aspect deals with dimensions of the gap in the area of the first surface. By the two etching processes performed, a length of the gap in the first surface region may be at least twice a value derived from an opening angle of the side walls of the inner region and the thickness of the tactical layer sequence. In other words, the more inclined the side walls of the inner region are due to the first etching process, the greater the distance of the gap from the two corners and side edges in the region of the first surface.

Other aspects deal with the further process after forming the gap in the epitaxial layer sequence. Thus, in some aspects, the method further comprises applying a mirror layer to the side flanks of the epitaxial layer sequence facing away from the inner region. In another aspect, the gap is filled, in particular with a transparent material. The transparent material can be non-conductive, so that a short circuit between the mirrored layer and the inner region is avoided. In another aspect, the gap can also be filled with a material comprising converter particles. In some aspects, the converter particles are designed as quantum dots and are suitable for converting light of a first wavelength generated in the inner region into light of a second wavelength. Depending on the embodiment, it is possible to perform a so-called full conversion. In some aspects, the second contact layer on the inner region has a reflective material for this purpose, so that light is not emitted from this second contact region during operation of the arrangement, but rather is emitted into the gap and converted there.

In a further aspect, a transparent conductive material is now applied to the second contact layer, which runs at least partially over the gap formed. For this purpose, the material can be applied to the transparent material in the gap. Alternatively, it is also possible to form a bridge or other structure from the transparent material and then remove the material in the gap.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a first embodiment of an optoelectronic component;

FIG. 2 shows a second embodiment of an optoelectronic component;

FIG. 3 shows a third embodiment of an optoelectronic component;

FIG. 4 shows a cross-section of an optoelectronic device with some components to illustrate some aspects;

FIG. 5 shows several partial figures of top views of arrays of optoelectronic components with different shapes; and

FIGS. 6A to 6F show various intermediate steps of a process for manufacturing an optoelectronic component.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. Thus, it is possible to derive such relationships between the elements based on the figures. However, the proposed principle is not limited to this, but various optoelectronic components with different sizes and also functionality can be used in the invention. In the embodiments, elements with the same or similar effects are shown with the same reference signs.

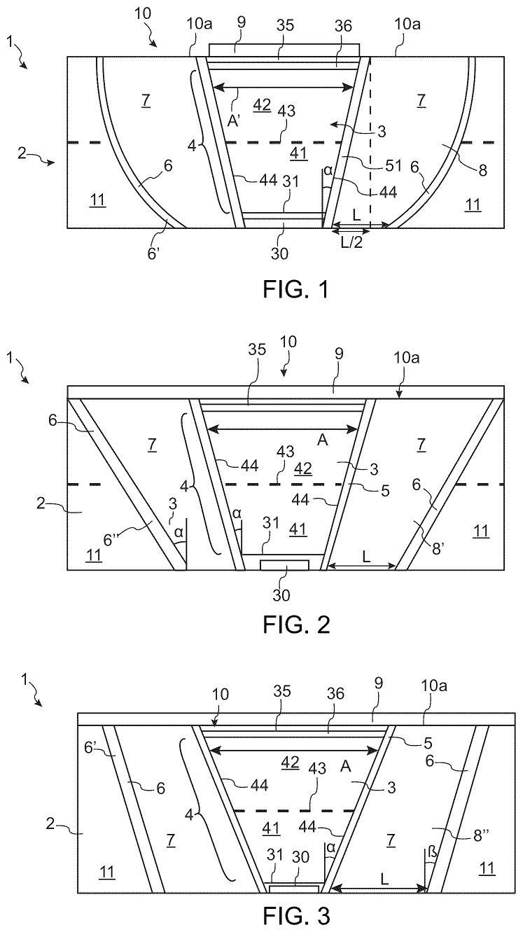

FIG. 1 shows a first embodiment of an optoelectronic component according to the proposed principle. The optoelectronic component is manufactured from an epitaxial layer sequence and essentially comprises an inner region 3, an gap 7 surrounding the inner region 3 and an outer area 11. The inner region 3 comprises functional semiconductor layers 4, which are designed to generate light. In simplified terms, these are referred to as vertical μ-LEDs, as the connection contacts 30 and 35 are arranged on opposite sides of the semiconductor layers 4. In detail, the μ-LED comprises a first p-doped layer 41, whereby the p-doping across the layer can either be constant or can also exhibit a predetermined doping gradient. The p-doped layer 41 is connected via a current distribution layer 31 to the first contact 30, which forms the underside of the μ-LED.

An active layer 43 is applied to the p-doped layer 41. In the present embodiment example, this comprises a quantum well for generating light, for example a blue or green color. A second semiconductor layer 42, which is also n-doped, is epitaxially deposited on the active layer 43. As in the p-doped epitaxially deposited layer 41, the second layer 42 also has a constant doping profile or, depending on the desired application, a variable doping profile. An optional current distribution layer 36 is formed on the upper side of the second layer 42 and the second contact 35 is formed on this. The upper side of the second contact 35 thus also forms part of the light-emitting surface 10 of the electronic component.

The side walls 44 of the functional inner region 3 are covered with a dielectric and transparent passivation layer 5. As shown, the side walls do not run perpendicular to a surface normal of the light exit side 10, but are inclined outwards by an angle α to it. As shown here, this results in a base area of the inner region 3 of the semiconductor layers 4 increasing constantly and continuously from the first contact 30 to the second contact 35. In other words, the inner region 3 is designed with beveled side surfaces and is therefore funnel-shaped.

A transparent conductive layer 9, for example made of ITO, is applied to the light exit side of the second contact 35. This completely covers the contact 35, which extends over the entire outlet side.

In addition, the optoelectronic component comprises an area 11 of the epitaxial layer sequence, to the side walls of which the metallic mirror layer 6 is applied. In a cross-sectional view, the metallic mirror layer 6 has a parabolic shape, i.e. it opens increasingly in the direction of the light exit side 10. This creates a gap 7 between the electrical passivation layer on the side walls of the inner region 3 and the mirror layer 6, which is filled with a transparent and non-conductive material 8 as shown in the embodiment example. The plane 10a of the gap 7 parallel to the top of the contact 35 forms the light exit side 10 together with the surface of the contact 35.

The parabolic curve shown here for the mirror layer 6 along the side walls of the area 11 is designed in such a way that in the area of the first contact 30, a distance L between the mirror layer 6 and the dielectric layers 5 corresponds approximately to two times the opening angle α.

The structure shown here thus provides sufficient spatial separation between the mirror layer 6 and the dielectric passivation layer 5 so that they can both be processed and optimized independently of each other. As already indicated in the figure, the optoelectronic component is manufactured from a areal epitaxial layer sequence itself, so that areas 11 of the epitaxial layer sequence have at least partially the same structure and the same composition as the semiconductor layers 4. In particular, depending on the material system, a structure may also be present in these areas 11 that is also arranged in the functional layer sequence as active layer 43. In contrast to this active layer 43, the part arranged in the areas 11 is not used to generate light during operation of the optoelectronic component and is not configured for this purpose.

The spatial separation between the mirror layer 6 and the dielectric passivation layer 5 shown here in accordance with the invention makes it possible not only to individually optimize the layers but also to realize different geometries with regard to the inner region 3 and the surrounding gap 7. FIGS. 2 and 3 show various alternative embodiments to FIG. 1 in this respect.

In FIG. 2, both the shape of the gap 7 and the shape of the inner region 3 are funnel-shaped. Here, the inclination of the dielectric passivation layer 5 is determined by the angle α, i.e. the angle to the normal of the light emission side 10. Correspondingly, an angle β can be specified that defines the inclination of the mirror layer 6 relative to the normal to the light emission side 10. In this embodiment example, the angle β, i.e. the angle of inclination of the mirror layer 6 is greater than the corresponding angle α, i.e. the angle of inclination of the side surfaces of the inner region 3. It follows that the opening angle of the mirror layer and thus of the gap 7 is greater and thus the gap 7 opens more from the plane of the contact 30 to the light-emitting side than the corresponding inner region 3 with the functional semiconductor layers 4.

In addition, the dielectric passivation layer 5 has a slightly greater thickness in the area of the second contact 35 than in the area of the first contact 30. This circumstance is due to the manufacturing process, when a greater amount of material for the dielectric passivation layer is deposited on the side walls in the area of the later second contact 35 than in the area of the first contact 30.

In this embodiment, the mirror layer 6 also comprises a DBR mirror consisting of several layers with different refractive indices. A transparent contact material 9 is applied over the entire surface of the light exit side 10 and thus completely covers both the contact 35 and the gap 7. This is different from FIG. 1, in which the transparent conductive material 9 only partially covers the gap 7 (namely out of the drawing plane or into the drawing plane).

FIG. 3 shows an opposite example to the embodiment of FIG. 2, in which the angle of inclination β of the mirror layer is slightly smaller than the angle of inclination α of the passivation layer 5 on the side walls of the inner region 3. In this embodiment example, the distance L in the region of the first contact 30 between the passivation layer 5 and the mirror layer 6 is thus greater than in the region of the light exit side. Furthermore, in this embodiment example, overgrowth was carried out during the manufacturing process, so that the active layer 43 originally present in the epitaxial layer sequence is now only present in the inner region 3 and thus forms part of the layer sequence 4. In the neighboring areas 11, on which the mirror layer 6 is applied, on the other hand, areas corresponding to the active layer 43 were largely eliminated by the overgrowth process.

The embodiments shown here allow different geometries and sizes to be provided for both the inner region 3 and the surrounding gap 7. In some embodiments, a geometric shape of the inner region 3 in plan view is the same as the geometric shape of the surrounding gap 7 and the mirror layer 6. However, this is not absolutely necessary, so that the two shapes can also differ from one another. Irrespective of this, however, it is possible to create different designs with regard to the shape of the gap and the mirror layer 6 attached to it. FIG. 5 shows 3 partial figures, each showing different embodiments in plan view of one or more optoelectronic components according to the proposed principle.

In the left partial figure, 3 hexagonal optoelectronic components are shown according to the proposed principle. One side of each of the hexagons lies parallel to another side of a neighboring component. The distance d between two neighboring components is chosen to be the same, although this distance can vary depending on the application. In extreme cases, the optoelectronic components produced using the method proposed in this application can be in close contact, i.e. their distance from each other is essentially zero and the mirror layers 6 touch each other conductively in the area of the light-emitting surface.

In the left partial figure, the hexagonal optoelectronic components are completely overgrown with a transparent cover layer 9 so that a common n-contact is realized between the individual components. Each component comprises an inner region 3, which together with the gap 7 forms the exit surface 10. The plane 10a of the gap is filled with a transparent material.

The middle section of FIG. 5 shows a further embodiment in which the optoelectronic components are circular in plan view. The inner region is also circular with its contact 35 and is connected to the outer area of the epitaxial layer sequence 2 and thus to the metallically conductive mirror layer 6 via a metallic bridge 9a. The gap 7 between the inner region 3 and the surrounding areas 11 comprising the remaining epitaxial layer sequence 2 is designed as a hollow body in this embodiment example, i.e. it is not filled with a solid material, but only with a gaseous material. This is air or an inert gas such as N2. The bridges 9a thus form a bridge. During manufacture, such a bridge is created by filling the gap 7 with a temporary material, then forming the bridge 9a and removing the temporary material from the gap 7.

In the right-hand partial figure of FIG. 5, the optoelectronic components are designed as square components with a square inner region 3 and a square gap 7 surrounding the square inner region. Here too, the gap 7 is filled with a material so that a continuous areal and transparent contact is formed on the light emission side.

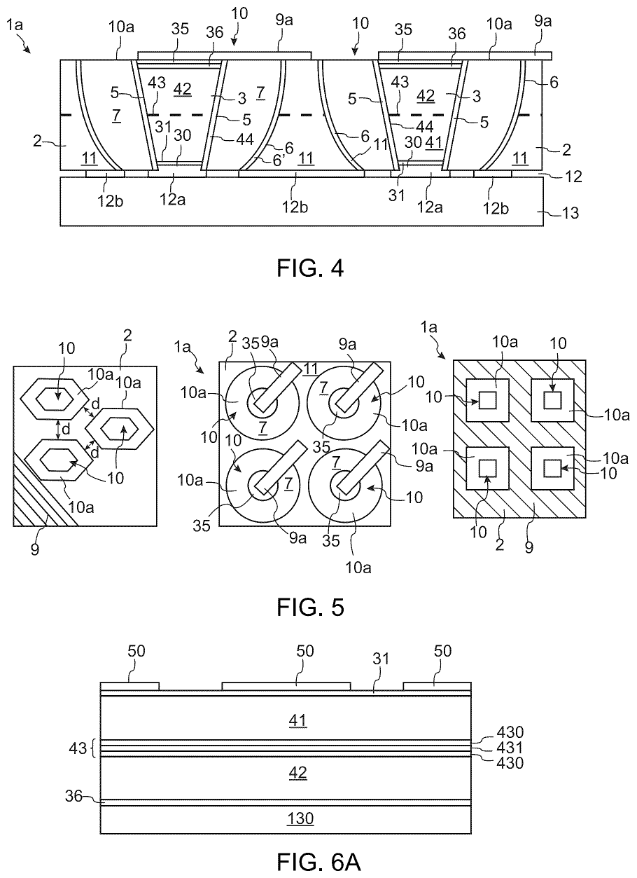

The embodiments shown here can be combined to form an optoelectronic device, which can be designed as a display with a large number of such μLEDs in an epitaxial layer sequence. FIG. 4 shows a cross-sectional view of such an optoelectronic arrangement 1a. Several inner regions 3, designed as vertical μ-LEDs, are produced from an epitaxial layer sequence 2, and their side walls are each surrounded by a dielectric passivation layer 5. At a distance from this, a mirror layer 6 is applied to the remaining parabolically structured areas 11 of the epitaxial layer sequence 2. The mirror layer 6 is made of a metallic material 6′ so that an electric current can flow along the mirror layer 6. Several contact bars 9a are arranged on the light exit side of each optoelectronic component and connect the mirror layer 6 in an electrically conductive manner to the second contact 35 of the respective inner regions 3 of the μ-LEDs.

According to the proposed principle, the optoelectronic device further comprises an insulating layer 12 grown or arranged adjacent to the first contacts 30 on the underside of the epitaxial layer. The insulating layer 12 comprises, for example, SiO2 or another insulating material and includes a plurality of openings which are in turn filled with a conductive material.

First openings 12a are arranged directly above the first contact 30, so that the conductive material contained therein makes electrical contact with this contact 30. Second contact areas 12b, however, either contact the mirror layer 6 directly, as for example in the two areas shown on the left and right of the figure, or also the area 11 adjacent to the mirror layer 6. This aspect is shown for the middle area 11 between the two μ-LEDs.

The area 11 is made of the same material as the semiconductor layer 41, i.e. it has conductive properties and can therefore establish an electrical connection between the area 12b and the mirror layer 6. In this way, contact elements are arranged on the underside, i.e. the insulating layer 12, with the aid of which the individual optoelectronic components of the device can be individually controlled. The openings filled with material are in turn connected to contacts of a control layer 13, which contain the necessary supply and control elements for individual control of the individual optoelectronic components of the arrangement. The control layer 13 is often manufactured separately for this purpose, so that it can be formed from a different material system to the material system of the epitaxial layer sequence 2.

In this way, optoelectronic devices can be formed with a large number of optoelectronic components that are made from a single continuous epitaxial layer. The material system of the epitaxial layer can be selected differently depending on the requirements. For example, it is possible to provide a material system for generating blue light. To generate mixed light in either a half or full conversion, the gap 7 is filled with a converter material containing converter particles.

To generate a full conversion, the second contact 35 can be designed with a metallic reflective layer so that the light emitted upwards is reflected by it and emitted into the gap. There it is converted and emitted on the light exit side 10 through the plane 10a of the gap 7. Various converter materials in the gap 7 make it possible to form red and green light from a blue pump light of the semiconductor layers 4. To generate blue light, the gap is simply filled with a transparent material or left open.

Quantum dots in particular can be used as converter materials, as these are particularly small and can be introduced into the gap in high density and concentration. Alternatively, it is also possible to fill the gap with a polymer containing converter materials.

Alternatively, other material systems can also be used, for example to generate red light, which are based on indium-containing quaternary or ternary material systems. In this case, an overgrowth process is often carried out during the manufacturing process so that the band gap of the active regions 43 in the area of the passive dielectric layer 5 is changed. This overgrowth process often also destroys the area of the active layer 43 located between two optoelectronic components, so that it overgrows as shown in FIG. 3 and is thus largely changed. Depending on the configuration, an active area 43 can therefore also be provided in the space between two neighboring optoelectronic components. Electronically, this area would not be suitable for generating light, as it would not be subjected to a voltage greater than the threshold voltage in the direction of flow during operation. In the event of overgrowth, the energy band structure of this area is also changed in such a way that it is no longer suitable for generating light.

Depending on this, further optical elements can be provided on the light emission side for shaping or converting the emitted light.

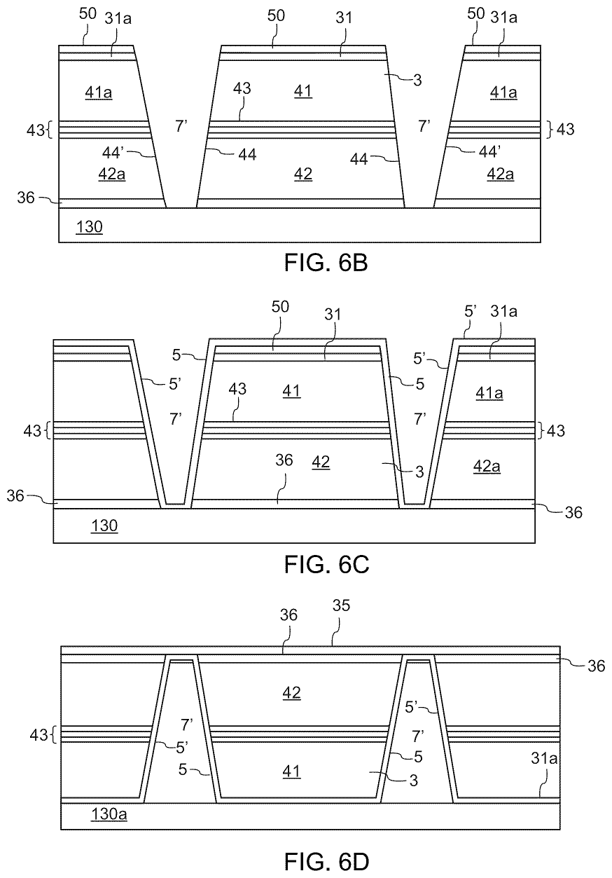

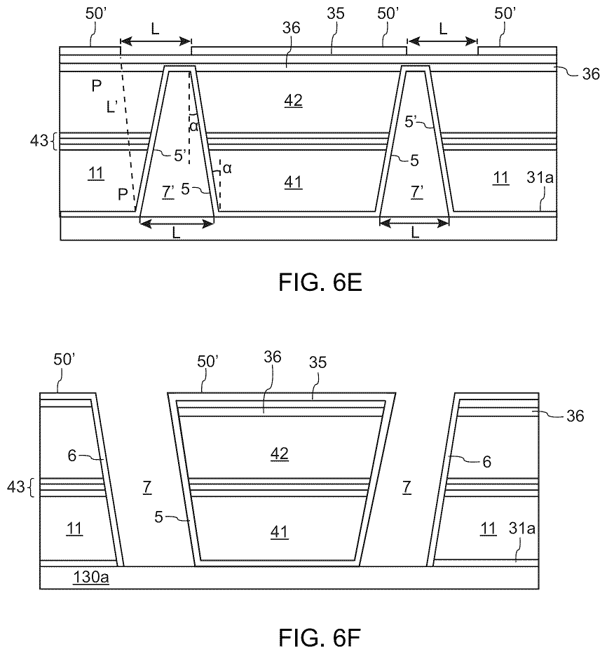

FIGS. 6A to 6E show the results of various intermediate steps for a process for manufacturing an electronic component according to the proposed principle.

FIG. 6A shows the production of an epitaxial layer sequence on a carrier and growth substrate 130. For this purpose, a carrier and growth substrate 130 is provided which is suitable for epitaxial deposition of various semiconductor layers. In addition to a buffer layer not shown here, further layers can be deposited epitaxially. A current expansion layer 36, which in the present case is n-doped, is shown as an example. During operation, the current expansion layer 36 serves to distribute charge carriers over as large an area as possible of the n-doped semiconductor layer 42 deposited on it and to inject them. A multiple quantum well structure 43 is applied to the n-doped semiconductor layer 42. This comprises a plurality of alternately arranged barrier layers 430 and quantum well layers 431. The thickness of the barrier and quantum well layers is selected differently and is in the range of a few nanometers. Depending on the material system, the barrier layers can be created by changing the aluminium concentration during the cutting of the material.

After applying the multiple quantum well structure 43, a second p-doped semiconductor layer 41 is deposited. A further current-expanding layer 31 is then applied to this layer over the entire surface of the epitaxial layer sequence.

The epitaxial layer sequence produced in this way is optimized for a specific wavelength to generate light. This can be blue light, green light or red light, for example. In all cases, the wavelength can be adjusted accordingly by adding indium in a material system based on GaN, for example InGaN, InGaP, InAlGaN or InAlGaP.

In the next step, a paint structure mask is applied to the layer 130 forming the first surface and this is structured in the shape shown. A top view of this mask shows, for example, a shape in which areas of the current conditioning layer 31 are exposed and enclose an inner surface covered with lacquer material. The shape of the inner surface and the outer edges of the lacquer layer depends on the application and can, for example, have the design shown in the partial figures in FIG. 5.

The exposed areas of the current expansion layer 31 are then subjected to an etching process and thus a mesa structure is etched into the epitaxial layer sequence, forming trenches 7′. FIG. 6B shows the result of such a medical process, in which an inner region 3 is surrounded by mesa trenches 7′. These mesa trenches have a side flank that is essentially symmetrical and whose inclination is defined by the angle α with respect to a normal. The process shown here thus removes the material in the mesa trenches 7′ of the semiconductor layer sequence 41, the multiple quantum well structure 43 and the second semiconductor layer 42 down to the growth substrate 130. Alternatively, this process can also end in the buffer layers not shown here between the growth substrate 130 and the current expansion layer 36 or also within the current expansion layer 36 or in the semiconductor layer 42, if this appears expedient. The photoresist layer 50 remains on the upper side.

The layer 50 applied in the previous process can be used at least partially for the further process steps and serves as a protective layer over the current conditioning layer 31 for the following process step. FIG. 6C shows the next step in this respect, in which the side walls of the inner region are covered with a passivation layer 5. The passivation layer is also deposited on the averted side surfaces as layer 5′, as well as on the top of the photoresist layer 50. These layers 5′ are undesirable in themselves and are removed again by the further process steps.

After the passivation layer has been formed accordingly, the epitaxial layer sequence is rebonded, in which an additional support 130a is applied to the top of the epitaxial layer sequence and attached to it. The additional carrier 130a thus covers the openings of the mesa trenches 7′. The growth substrate 130 is then removed and the resulting surface is prepared for further process steps. FIG. 6D shows a further process step in which a second metallic contact layer 35 is applied to the surface of the current distribution layer 36 after rebonding. As with the first metallic contact layer, this can also be used as a structured layer for the further process steps and in particular for the second etching process to form the gap. Alternatively, it is also possible to apply a further photoresist layer to the second contact layer 35, to structure it and then to subject the epitaxial layer sequence to a further process.

According to FIG. 6E, a further photoresist layer 50′ is now applied to the surface of the second contact layer 35 and structured accordingly. In the process, areas are removed from the photoresist layer 50′ that are at least partially above the gap 7′ created by the first etching process. Specifically, areas of the second contact layer 35 are exposed in this way which, on the one hand, terminate in their extension with the passivation layer 5 on the side flank of the inner region 3 and, on the other hand, lie over a partial area of the epitaxial layer sequence outside the inner region. The width L of this structure is selected such that it corresponds at least to the width L of the first mesa structure 7′ in the area of the first contact layer.

In FIG. 6E, this is shown by drawing an imaginary extension line L′ between the two points P, which is parallel to the passivation layer 5. This results in a virtual displacement of the gap by a distance that depends on the arcsine of the angle α, where the angle α is defined between the surface normal and the archiving layer 5.

The material of the exposed surface of the epitaxial layer sequence is removed in a second etching process, whereby this etching process also produces an inclined side flank in the epitaxial layer sequence. During this process, undesired and remaining components of the passivation layer 5′ on the inner flank of the passivation layer in the areas 11 are also removed. The result is a side flank of the remaining epitaxial layer sequence in the areas 11 which has essentially the same angle of inclination as the passivation layer 5. With a greater distance L on the surface of the second contact layer 35, the angle of inclination of the side flank of the epitaxial layer sequence can also be more inclined, resulting in a funnel-shaped configuration which increases from the first contact side towards the second contact side.

The result of the etching process is shown in FIG. 6F, where a metallic mirror layer 6 is also applied to the surface of the side flank in area 11. In a final step, the gap 7 formed in this way is filled flush with a transparent material up to the top of the second contact layer 35. The remaining photoresist layer 50′ is removed so that the transparent material is flush with the top of the contact layer 35. Together with the surface of the transparent material in the gap, the second layer 35 forms the light-emitting side of the electronic component formed in this way.

For electrical contacting of the electronic components via the second contact layer 35, a transparent conductive material (not shown here) is also applied to the surface. The material comprises, for example, ITO and extends from the second contact layer 35 via the gap 7 to the metallic mirror layer 6. It thus contacts the metallic mirror layer 6 in a conductive manner and connects it to the second contact layer 35. During operation of this component, a current flows via the areas 11 and the conductive mirror layer 6 into the second contact. At the same time, the first contact layer is electrically contacted adjacent to the carrier 130a, so that charge carriers are injected into the respective semiconductor layers 41 and 42 and combine with each other in the active layer to generate light. The light is emitted to all sides and, in the case of side emission, reaches the metallic mirror layer 6, is reflected there and emitted in the direction of the light exit side.

Different variations are also conceivable for the processes described here. For example, in addition to a different length for the second etching, further measures can be taken to improve the side edges, such as quantum well intermixing in the area of the active layer. It is also possible to carry out the second etching in several stages, so that the result is not just a linear process as shown in FIG. 6F, but a curved parabolic or circular one, for example. In subsequent process steps, the additional carrier substrate 130a can be replaced by an insulating layer which has openings in the region of the mirror layer 6 and in the region of the first contact adjacent to the semiconductor layer 41. These openings are in turn filled with an electrically conductive material, so that the vertical component with its inner region one has two contact areas on a single side and is contacted via them. Of course, the carrier substrate can also be formed with such an insulating layer, or this can also be applied before bonding.

Due to the spatial separation between the mirror layer 6 and the archiving layer 5 of the μ-LED, these can be optimized differently in relation to each other. In particular, a different inclination of the mirror layer in relation to the passivation layer can be realized, whereby different radiation characteristics can also be set. This makes it possible to easily shape the light of the component.

Irrespective of the manufacturing process carried out here, further optics can be provided on the optoelectronic component according to the proposed principle, which are suitable for corresponding light shaping or collimation. Several such components can be implemented in the epitaxial layer sequence, which are interconnected in a suitable manner and thus form part of a display array or pixel array. In particular, by selecting suitable gaps 7 and fill these with converter materials it is possible to generate different pixel colors by full conversion.

1.-31. (canceled)

32. An optoelectronic component with an epitaxial layer sequence comprising:
a functional inner region comprising a first electrical contact and a second electrical contact opposite the first electrical contact, and semiconductor layers arranged between the first electrical contact and the second electrical contact being configured to generate light, wherein the semiconductor layers comprise a base area that increases towards the second electrical contact;
a dielectric passivation layer on sidewalls of the semiconductor layers configured; and
a mirror layer surrounding the passivation layer at a distance thereby forming a gap,
wherein the second electrical contact and a plane of the gap surrounding the second electrical contact form a light-emitting surface,
wherein the semiconductor layers comprise a first semiconductor layer having a first dopant type electrically connected to the first contact, a second semiconductor layer of a second doping type electrically connected to the second contact, and an active layer arranged between the first and second semiconductor layers, and
wherein regions of the epitaxial layer sequence, on which the mirror layer is arranged, comprise at least one of the first semiconductor layer, the second semiconductor layer or the active layer.

33. The optoelectronic component according to claim 32, wherein the mirror layer is electrically conductive and contacts the second electrical contact.

34. The optoelectronic component according to claim 32, further comprising an electrically conductive transparent material extending at least partially over the gap and contacting the second electrical contact.

35. The optoelectronic component according to claim 34, wherein the electrically conductive transparent material comprises ITO and/or extends areal over the second electrical contact and the gap or extends as a bridge from the second electrical contact at least to the mirror layer.

36. The optoelectronic component according to claim 32, wherein the gap comprises at least one of the following:
a transparent, non-conductive material, which at least partially fills the gap,
a converter material comprising quantum dots or a polymer provided with converter particles or organic fluorescent dyes, or
a gas so that the gap is at least partially free of a solid material.

37. The optoelectronic component according to claim 32, wherein the mirror layer comprises at least one of the following:
a metallic electrically conductive layer comprising silver, gold, platinum or another material that is highly reflective for the light generated,
a sequence of layers with different refractive indices, or
a DBR mirror.

38. The optoelectronic component according to claim 32, wherein the gap is, in a plan view of the light-emitting surface, circular or square or polygonal or is oriented in its shape to crystal lattice planes of the epitaxial layer sequence.

39. The optoelectronic component according to claim 32, wherein the mirror layer comprises a parabolic shape opening in a direction of the light-emitting surface.

40. The optoelectronic component according to claim 32,
wherein an opening angle between the mirror layer and a normal to the light-emitting surface is larger, at least in some regions, than an opening angle between the sidewalls of the semiconductor layers and the normal to the light-emitting surface,
wherein an opening angle between the mirror layer and a normal to the light-emitting surface is smaller, at least in some regions, than an opening angle between side walls of the semiconductor layers and the normal to the light-emitting surface, or
wherein an opening angle between the mirror layer and a normal to the light-emitting surface is, at least in some regions, substantially the same as an opening angle between the side walls of the semiconductor layers and the normal to the light-emitting surface.

41. The optoelectronic component according to claim 32, wherein the mirror layer opens substantially in a funnel shape in a direction of the light-emitting surface.

42. The optoelectronic component according to claim 32, wherein a ratio of distances from the mirror layer to centers of the first and second contacts, respectively, is different from a ratio of distances between the sidewalls of the semiconductor layers and the centers of the first and second contacts, respectively.

43. The optoelectronic component according to claim 32, wherein a distance between the mirror layer and the sidewalls of the semiconductor layers in a region of the first contact depends on an angle between a normal to the light-emitting surface and the sidewalls of the semiconductor layers and a thickness of the epitaxial layer sequence.

44. The optoelectronic component according to claim 43, wherein the distance is given by twice an arctan of the angle between a normal to the light-emitting surface and the sidewalls of the semiconductor layers multiplied by the thickness of the epitaxial layer sequence.

45. The optoelectronic component according to claim 32, wherein the active layer comprises at least one of the following:
one or more quantum well structures,
a quantum well intermixing in an area of side walls, or
an enlargement of a band gap in a region of the side walls.

46. The optoelectronic component according to claim 32, further comprising an insulating layer arranged on a side of the first contact and comprising at least two openings comprising an electrically conductive material, wherein the material in the first opening contacts the first contact and the material in the second opening contacts at least one of the mirror layer and a region on which the mirror layer is arranged.

47. An optoelectronic device comprising:
a plurality of components according to claim 32; and
at least one control layer on which the plurality of components are arranged and electrically contacted.

48. The optoelectronic device according to claim 47, wherein a distance between two components corresponds to at least a distance between two opposite points of the mirror layer in a region of the light-emitting surface.

49. A method for manufacturing an optoelectronic component, the method comprising:
providing a growth substrate;
forming an areal epitaxial layer sequence with an n-doped semiconductor layer, a p-doped semiconductor layer and an active layer arranged in between;
structuring a first surface of the epitaxial layer sequence such that, in plan view of the first surface, a surface area accessible to a first etching process encloses an inner surface;
conducting the first etching process and creating a mesa trench in the accessible surface area such that an inner region with inclined side flanks is created, wherein the mesa trench exposes at least the active layer of the epitaxial layer sequence;
structuring a second surface of the epitaxial layer sequence opposite the first surface such that, in plan view of the second surface, areas remain accessible to a second etching process, which lie at least partially above the mesa trench; and
conducting the second etching process such that a continuous gap is created around the inner region and the side flank of the epitaxial layer sequence opposite the inner region is at least partially inclined relative to a normal.

50. The method according to claim 49, wherein forming comprises at least:
applying a first electrical contact layer forming the first surface, or
applying a first electrical contact layer and a structured insulation layer, wherein the structured insulation layer forms the first surface.

51. The method according to claim 49, wherein structuring the first surface comprises creating a quantum well intermixing in areas of the active layer which, in extension, enclose an interface between the surface area accessible to the first etching process and the inner surface.

52. The method according to claim 49, wherein a surface region accessible to the first etching process comprises at least one of the following shapes in plan view:
a circular ring,
an outer edge in the form of a polygon,
an outer square edge, or
an inner edge in the form of a polygon.

53. The method according to claim 49, wherein creating the mesa trench comprises:
optionally treating a side surface of the inner region to reduce defects in a surface region of the active layer; and
passivating a surface of the side surface of the inner region.

54. The method according to claim 49, wherein structuring the second surface opposite the first surface comprises:
placing a carrier on the first surface and at least partially removing the growth substrate; and
optionally applying a second electrical contact layer on the second surface.

55. The method according to claim 49, wherein the areas of the second surface accessible to the second etching process are outside the inner region formed by the first etching process.

56. The method according to claim 49, wherein the side flank of the epitaxial layer sequence opposite the inner region is less inclined relative to a normal to the second surface than side walls of the inner region.

57. The method according to claim 49, wherein the side flank of the epitaxial layer sequence opposite the inner region comprises a parabolic shape with a decreasing diameter in a direction of the first surface.

58. The method according to claim 49, wherein a length of the gap in a region of the first surface is at least twice a value derived from an opening angle of side walls of the inner region and a thickness of the epitaxial layer sequence.

59. The method according to claim 49, further comprising applying a mirror layer on the side flanks of the epitaxial layer sequence facing away from the inner region.

60. The method according to claim 49, further comprising:
filling the gap with a transparent material;
filling the gap with a material containing converter particles, wherein a second contact layer on the inner region is optionally made of a reflective material; and
forming a transparent conductive material at least partially on the material which conductively connects a second electrical contact layer to a mirror layer.
